(19) United States
(12) Patent Application Publication
(10) Pub. No.: US 2016/0077135 A1
(43) Pub. Date: Mar. 17, 2016

(54) SHUNT CURRENT MEASUREMENT WITH TEMPERATURE COMPENSATION

(71) Applicant: Continental Teves AG & Co. oHG, Frankfurt (DE)

(72) Inventors: Wolfgang Jöckel, Gersfeld (DE); Henrik Antoni, Freigericht (DE)

(21) Appl. No.: 14/852,808

(22) Filed: Sep. 14, 2015

(30) Foreign Application Priority Data
Sep. 17, 2014 (DE) 10 2014 218 708.7

(51) Int. Cl. G01R 19/32; G01R 1/20

(52) U.S. Cl. CPC G01R 19/32; G01R 1/203

(57) ABSTRACT

A method for the measurement of an electric current by an electrical conductor in a vehicle, the electrical conductor having two conductor sections, between which a shunt is connected, the method including determining an electrical measuring voltage delivered via the shunt; recording a first corrective voltage in the direction of the electric current up-circuit of a given point on the shunt; recording a second corrective voltage in the direction of the electric current down-circuit of the point on the shunt; and determining the electric current based upon the electrical measuring voltage recorded and a difference between the first corrective voltage and the second corrective voltage.

### CROSS REFERENCE TO RELATED APPLICATIONS

This application claims priority to German Patent Application No. 10 2014 218 708.7, filed Sep. 17, 2014, the contents of such applications beign incorporated by reference herein.

### FIELD OF THE INVENTION

The invention relates to a method for the measurement of a current using a current sensor.

### BACKGROUND OF THE INVENTION

Electric currents flowing into and out of a vehicle battery are measured, for example in DE 10 2009 044 992 A1, which is incorporated by reference and in DE 10 2004 062 655 A1, which is incorporated by reference, by means of a current sensor using a measuring resistance, also described as a shunt. In both cases, in order to enhance the accuracy of current measurement, it is proposed that a temperature increase associated with power dissipation in the shunt should be compensated, in order to prevent the generation of thermoelectric voltages. The temperature increase associated with power dissipation is excluded accordingly.

### SUMMARY OF THE INVENTION

An aspect of the present invention is an improvement of the known method of current measurement.

According to one aspect of the invention, a method for the measurement of an electric current by means of an electrical conductor in a vehicle, whereby said electrical conductor is comprised of two conductor sections, between which a shunt is connected, comprises the following steps:
The determination of an electrical measuring voltage delivered via the shunt;
The recording of a first corrective voltage in the direction of the electric current, considered up-circuit of a given point on the shunt;
The recording of a second corrective voltage in the direction of the electric current, considered down-circuit of said point on the shunt; and
The determination of electric current, based upon the electrical measuring voltage recorded and a difference between the first corrective voltage and the second corrective voltage.

The method proposed is based upon the consideration that the compensation of temperature variations, as specified in the introduction, should be undertaken for the correction of measuring errors. These originate from thermoelectric voltages which corrupt the voltage drop associated with the flow of electric current in the shunt, such that the measurement of electric current is also defective. However, in the case described in the introduction, the correction of measuring errors on the basis of power dissipation requires complex modeling, which is time-consuming in each individual case.

In the method proposed, it is considered that thermoelectric voltages occur at the transitions between the conductor sections and the shunt and, in principle, will cancel each other out at the shunt, on the grounds that they are in mutual opposition. Measuring errors will only occur where the distribution of temperature giving rise to thermoelectric voltages in the electrical conductor, specifically at the above-mentioned transitions, is uneven. Only then will different thermoelectric voltages occur, resulting in measuring errors which will require correction.

In this respect, the method described proposes that only the uneven distribution of temperatures and/or of thermoelectric voltages on the electrical conductor giving rise to measuring errors should be considered, rather than the thermoelectric voltages or temperatures themselves. The uneven distribution itself can be detected from a voltage distribution on the electrical conductor, which also includes the corrective voltages. This voltage distribution will ultimately incorporate the thermoelectric voltages and the temperatures giving rise to said thermoelectric voltages, such that these will not require time-consuming modeling. Accordingly, the measuring error can be deduced directly from the voltage distribution and from the two corrective voltages, which can then be considered in the measurement of the electric current.

The point, up-circuit and down-circuit of which the two corrective voltages are to be measured should be selected such that the first corrective voltage and the second corrective voltage are recorded symmetrically to said point. This means that, firstly, the material properties of the electrical conductor should show a symmetrical profile in relation to this point. In addition, the voltage tap-off points should also be arranged symmetrically to this point. By this arrangement, from the voltage distribution which includes the consideration of the two corrective voltages, it is possible to detect actual temperature differences and, accordingly, thermoelectric voltages via the electrical conductor.

In a further development of the method described, an electrical resistance at a reference temperature by means of which the first corrective voltage is recorded, is equal to an electrical resistance at a reference temperature by means of which the second corrective voltage is recorded. By this arrangement, for example, the above-mentioned symmetry of material properties can be achieved.

In an additional further development of the method described, both electrical resistances are provided with equal temperature coefficients whereby, alternatively or additionally, the above-mentioned symmetry of material properties can be achieved.

In a specific further development, the method described comprises the following steps:
The determination of a temperature difference based upon the difference between the first corrective voltage and the second corrective voltage, and
The determination of electric current, based upon the electrical measuring voltage and the temperature difference recorded.

For the determination of electric current on the basis of the electrical measuring voltage and the temperature difference recorded, in a known arrangement, a difference between the thermoelectric voltages, by which said thermoelectric voltages do not cancel each other out can be deduced, for example, from the temperature difference. The measuring voltage can then be corrected by this difference in the thermoelectric voltages.

In another further development of the method described, the corrective voltages can be determined respectively at a transition between the conductor sections of the electrical conductor and the shunt. By this arrangement, thermoelectric voltages can be recorded directly.

Thereafter, in accordance with the method described, it is possible to determine the above-mentioned difference between the thermoelectric voltages, based upon the difference between the corrective voltages determined respectively for a transition between the conductor sections of the electrical conductor and the shunt, whereby the electric current can then be determined on the basis of the electrical measuring voltage recorded and the difference between the thermoelectric voltages.

Naturally, it is also possible to combine the two above-mentioned further developments of the method described, for example, in the interests of the exploitation of redundancies in compensation.

In a further development of the method described, the two corrective voltages are recorded at a common voltage tap-off point, in order to restrict the number of voltage tap-off points to be provided to a minimum.

According to a further aspect of the invention, a control device is provided for the execution of a method according to one of the above-mentioned claims.

In a further development of the control device described, the device described comprises a memory and a processor. The method described is stored in the memory in the form of a computer program, and the processor is designed to execute the method, when the computer program is loaded from the memory into the processor.

According to a further aspect of the invention, a computer program incorporates program code means for the execution of all the steps of one of the methods described, when the computer program is run on a computer or on one of the devices described.

According to a further aspect of the invention, a computer program product incorporates a program code which is stored on a computer-readable data storage medium and which, when run on a data processing device, executes one of the methods described.

According to a further aspect of the invention, a current sensor for the measurement of an electric current incorporates an electric shunt, via which the electric current to be measured is routed to one of the control devices described.

According to a further aspect of the invention, a vehicle incorporates one of the control devices described and/or the current sensor described.

### BRIEF DESCRIPTION OF THE DRAWINGS

The above-mentioned properties, characteristics and advantages of the present invention, and the means whereby these are to be achieved, are further explained and clarified with reference to the following description of exemplary embodiments, which are described in greater detail with reference to the figures, wherein:

FIG. 1 shows a schematic representation of a vehicle with an electric drive system;

FIG. 2 shows a schematic representation of a current sensor from the vehicle represented in FIG. 1,

FIG. 3 shows a circuit diagram of the current sensor represented in FIG. 2;

FIG. 4 shows a schematic representation of an alternative current sensor from the vehicle represented in FIG. 1; and

FIG. 5 shows a circuit diagram of the alternative current sensor represented in FIG. 4.

### DETAILED DESCRIPTION OF THE PREFERRED EMBODIMENTS

In the figures, the same technical elements are represented by the same numbers, and are described only once.

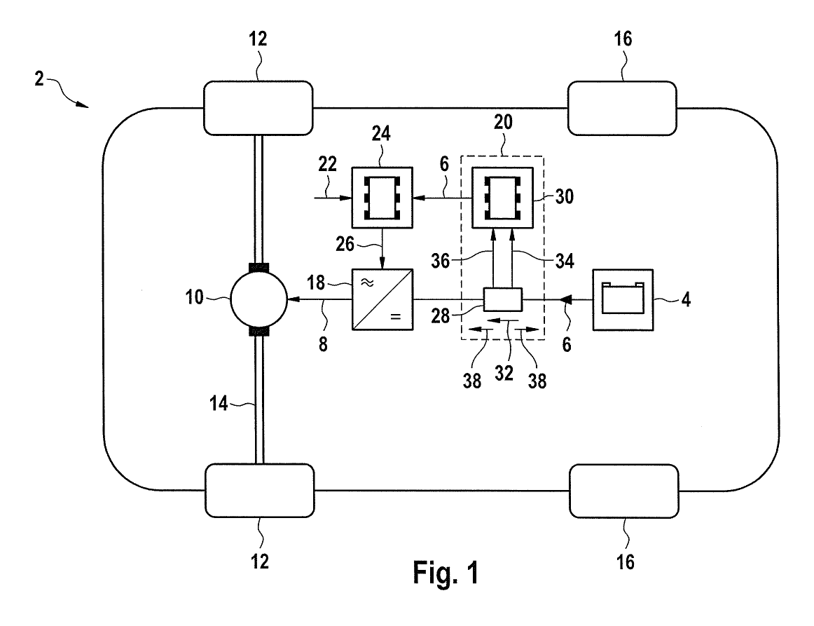

With reference to FIG. 1, a schematic representation is shown of a vehicle 2 with a vehicle battery 4, which delivers an electric current 6.

The electric current 6 supplies the various electrical consuming devices in the vehicle 2 with electrical energy 8.

One example of such electrical consuming devices is an electric motor 10, which uses electrical energy 8 to drive the front wheels 12 of the vehicle 2 via a drive shaft 14. The rear wheels 16 of the vehicle 2 are therefore free wheels. Electric motors 10 of this type used for the propulsion of a vehicle 2 are generally configured as alternating current motors, whereas the electric current 6 delivered by the vehicle battery 4 is a direct current. In this case, the electric current 6 must firstly be converted into an alternating current by means of a converter 18.

Vehicles, as in the case of the vehicle 2, are generally fitted with a current sensor 20 which measures the electric current 6 delivered by the vehicle battery 4. On the basis of the measured electric current 6, various functions can then be executed. These include, for example, protective functions, of the type known from DE 20 2010 015 132 U1, which is incorporated by reference, by means of which the vehicle battery 4 can be protected, for example, against exhaustive discharge.

Where the current 6 measured by the current sensor 2 only corresponds to the electric current which is routed to the converter 18, this current can also be used to control the drive power of the vehicle 2. The drive power is generally dictated by the driver of the vehicle 2 by means of a driver command 22. A motor control device 24 then compares the notional electric current resulting from the driver command with the measured electric current 6 and controls the converter 18 by means of control signals 26, such that the measured electric current 6 matches the notional current resulting from the driver command. Control systems of this type are exceedingly well-known, and will not be described in greater detail here.

The current sensor 20 incorporates a measuring detector, preferably configured as a measuring resistance 28, also described as a shunt, and an analyzing unit 30. In the present embodiment, electric current 6 flows through the shunt 28, resulting in a voltage drop 32 on the shunt 28. This voltage drop 32 is detected as a measuring voltage by the analyzing unit 30, with reference to an input-side electrical potential 34 on the shunt 28, considered in the direction of the electric current 6, and an output-side electrical potential 36 on the shunt 28. From these two electrical potentials 34, 36, the analyzing unit 30 calculates the voltage drop 32 and, from the resistance value of the shunt 28, calculates the electric current 6 flowing in the shunt 28.

As an electrical conductor, the shunt 28 is generally distinguished from the other electrical conductors which convey electric current 6 from the vehicle battery 4 to the converter 18.

By a known process, the thermoelectric effect, also described as the Seebeck effect, induces a thermoelectric voltage between a material transition in an electrical conductor which is subject to a temperature gradient, i.e. a difference in temperature. Due to the presence of the shunt 28, a material transition of this type is present on both the input side and the output side of the current sensor 20. A temperature difference occurs by definition, as a result of the heating of the shunt 28 resulting from the electric power dissipation associated with the flow of electric current 6. The resulting thermoelectric voltages 38 are added to the voltage drop 32, thereby invalidating the measurement of electric current 6.

In the present embodiment, it is therefore proposed that the measurement of electric current 6 should be corrected to take account of the thermoelectric voltages 38. In the present embodiment, this is achieved in the analyzing unit 30, and is described below:

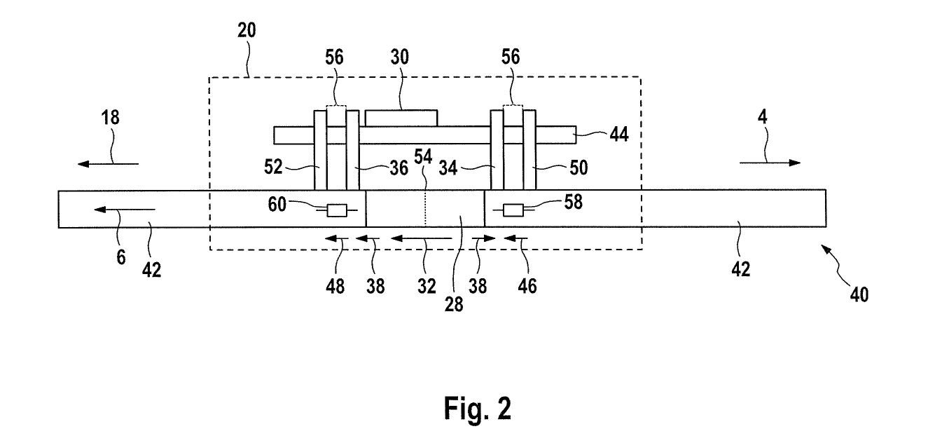

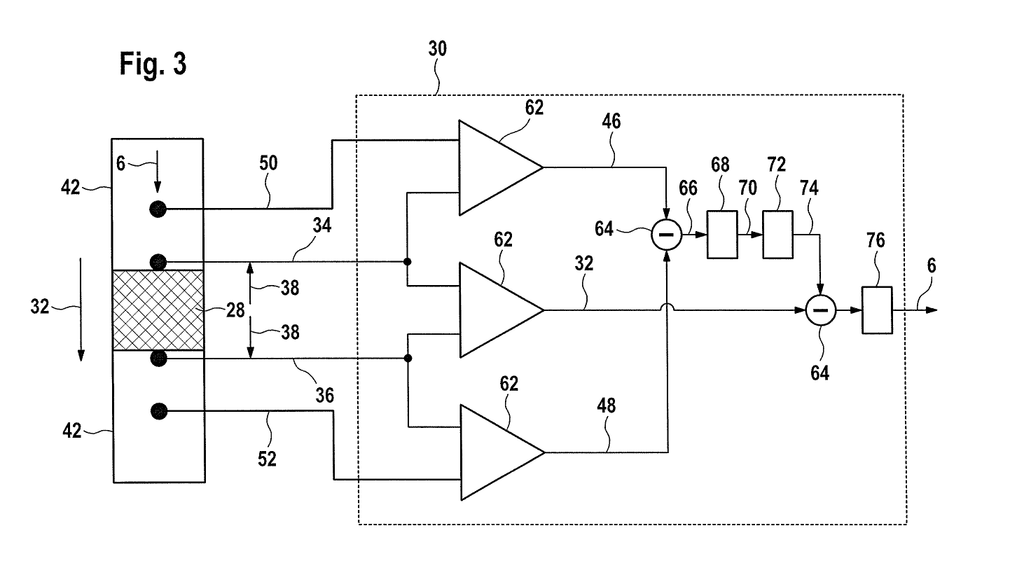

Reference is made to FIG. 2 and FIG. 3, which correspondingly show the current sensor 20 in a schematic representation, in accordance with a first exemplary embodiment, and a circuit diagram of the current sensor 20.

In the present embodiment, the current sensor 20 incorporates an electrical conductor 40, which is comprised of two conductor sections 42, between which the shunt 28 is connected. One of the two conductor sections 42 may be electrically connected to the vehicle battery 4, whereas the second of the two conductor sections 42 may be electrically connected to the converter 18. By this arrangement, the electric current 6 to be detected flows through the shunt 28.

The two electrical potentials 34, 36 are detected at a transition between one of the two conductor sections 42 and the shunt 28 in the direction of flow of the electric current 6, up-circuit and down-circuit of the shunt 28 and, in an arrangement not represented in greater detail here, are routed by means of a circuit carrier 44, such as a printed circuit board, for example, to the analyzing unit 30, such as may be wired to the circuit carrier 44.

In the present embodiment, for the correction of the above-mentioned thermoelectric voltages 38, it is proposed that a temperature distribution on the electrical conductor 40 should be detected and determined by means of a voltage distribution on the electrical conductor 40, and that any irregularity in the voltage distribution should be determined.

The voltage distribution is recorded and evaluated on the basis of at least a first corrective voltage 46 and a second corrective voltage 48.

As shown in FIG. 2, the first corrective voltage 46 may be recorded between the input-side potential 34 and a further input-side potential 50, considered in the direction of the electric current 6, up-circuit of the input-side potential 34. Correspondingly, the second corrective voltage 48 may be recorded between the output-side potential 36 and a further input-side potential 52, considered in the direction of the electric current 6, down-circuit of the output-side potential 36. In principle, the two corrective voltages 46, 48 should be recorded at a single point 54 on the shunt 28, considered in the direction of the electric current 6, correspondingly up-circuit of said point 54 and down-circuit of said point 54.

Appropriately, point 54 should notionally be arranged in the center of the shunt 28, such that the two input-side potentials 34, 50 and, accordingly, the first corrective voltage 46, and the two output-side potentials 36, 52 and, accordingly, the second corrective voltage 48, should be selected symmetrically in relation to said point 54. This means that both should observe an interval 56 between the input-side potentials 34, 50, equal to an interval 56 between the output-side potentials 36, 52, whereby a material of the electrical conductor between these intervals 56 should also be uniform.

In the present embodiment, Manganin, for example, may be selected as the constituent material of the shunt 28, whereas copper may be selected as the constituent material of the conductor sections 42. In this case, the material between the intervals 56 would be copper. “Manganin” is the proprietary name of a copper-manganese alloy with a composition of 82-84% copper and 12-15% manganese. Optionally, a 2-4% nickel content may be included.

From the corrective voltages 46, 48 recorded and, accordingly, from the voltage distribution recorded, a temperature distribution may then be deduced. From this temperature distribution it will then be evident whether the temperature of the electrical conductor 40 up-circuit of the shunt 28 changes in relation to the temperature of the electrical conductor 40 down-circuit of the shunt 28, as a result of which the above-mentioned thermoelectric voltages 38 will be significantly different, and will not cancel each other out accordingly.

For the determination of the temperature distribution, the interval 56 between the input-side potentials 34, 50 is considered as a first conductor resistance 58 and the second interval 56 between the output-side potentials 36, 52 is considered as a second conductor resistance 60. These conductor resistances 58, 60 are temperature-dependent, in accordance with the known relationship:

R=R₂₀(1+α₂₀*(T−T₂₀)),

where
R is the resistance value of the conductor resistances 58, 60 at the desired temperature;
R₂₀ is the resistance value of the conductor resistances 58, 60 at a reference temperature,
α₂₀ is a temperature coefficient which describes the temperature dependence of the material of the conductor resistances 58, 60,
T is the desired temperature; and
T₂₀ is the reference temperature.

For the correction of the above-mentioned thermoelectric voltages, it is not necessary for the temperature distribution itself to be known. It is sufficient that a temperature difference between the corrective voltages 46, 48 and, accordingly, the conductor resistances 58, 60, should be known. For example, if the resistance value of the first conductor resistance 58 is designated as R₁, the resistance value of the second conductor resistance 60 is designated as R₂ and, correspondingly, the desired temperature of the first conductor resistance value 58 is designated as T₁ and the desired temperature of the second conductor resistance value 60 is designated as T₂, the temperature difference may be determined as follows:

R₁−R₂=R₂₀(1+α₂₀*(T₁−T₂₀))−R₂₀(1+α₂₀*(T₂−T₂₀))

[symbol]

R₁−R₂=R₂₀*α₂₀*(T₁−T₂₀−T₂+T₂₀)

Given that, by definition, the two conductor resistances 58, 60 are arranged in series in the current sensor 20, the current 6 to be measured will have an influence upon the absolute temperature of the two conductor resistances 58, 60, but no influence upon the temperature difference T₁−T₂ between the two conductor resistances. This is purely dependent upon the voltage difference U₁−U₂ between the two conductor resistances. The above equation may therefore be simplified as follows:

T₁−T₂=(U₁−U₂)/(R₂₀*α₂₀)

U₁ is the first corrective voltage 46 and U₂ is the second corrective voltage 48. From the difference (U₁−U₂) between the two corrective voltages 46, 48, it is then possible to directly deduce the temperature difference (T₁−T₂) via the shunt 28, from which the inequality between the two thermoelectric voltages 38 can then be determined which will need to be compensated in the recorded electric current 6.

The corrective voltages 46, 48, as with the voltage drop 32 in the shunt 28, may be determined using the differential amplifiers 62 represented in FIG. 3. From the two corrective voltages 46, 48 it is then possible by means of a subtraction element 64, for example in the analyzing unit 30, to determine the voltage difference (U₁−U₂) between the two corrective voltages 46, 48, which is represented in FIG. 3 by the reference number 66. On the basis of the voltage difference 66, in a temperature difference determination device 68, it is then possible to determine the temperature difference (T₁−T₂) by the application of the above equation, represented in FIG. 3 by the reference number 70. From the temperature difference 70, in a corrective device 72, it is then possible to determine the thermoelectric voltage difference 74 between the thermoelectric voltages 38. With this thermoelectric voltage difference 74, the measuring voltage 32, prior to the determination of the electric current 6, can be corrected by the application of a further subtraction element 64 in a corresponding determination device 76.

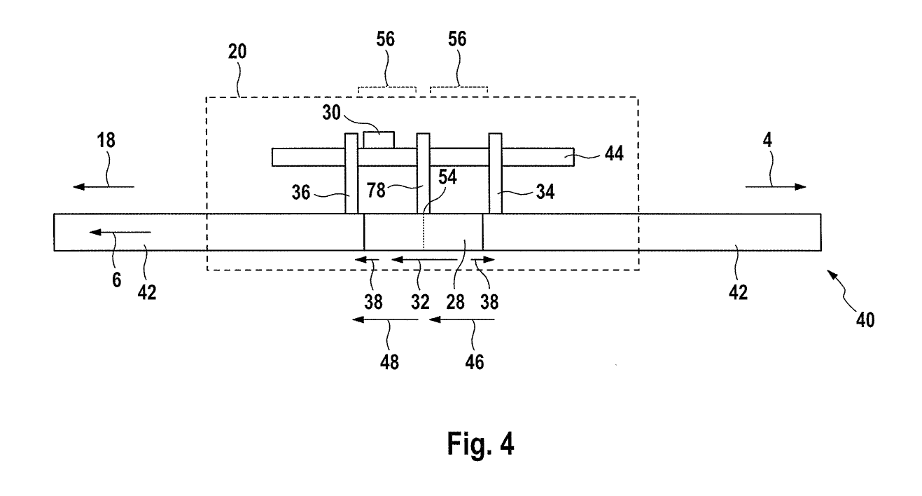

As an alternative to the method described with reference to FIG. 2 and FIG. 3, for the compensation of thermoelectric voltages 38 in the electric current 6, the further input-side potential 34 and the further output-side potential 36 may be set to a common potential 78 which, as shown in FIG. 4, may be set, for example, with reference to point 54.

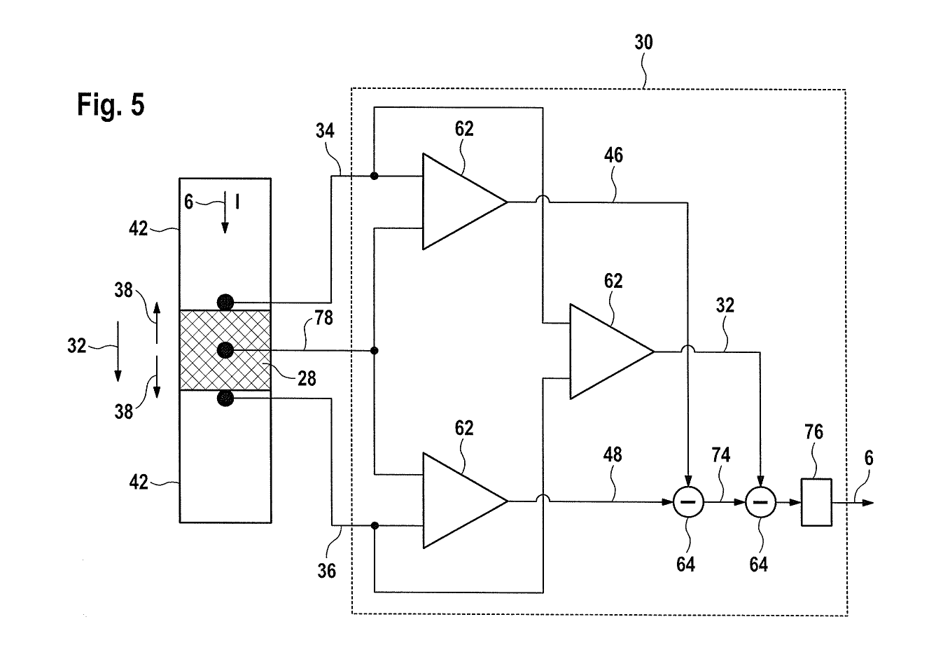

As the shunt 28 is generally selected such that its resistance value is substantially independent of temperature, as in the above-mentioned case of Manganin, for example, the resulting corrective voltages 46, 48 will cancel each other out quantitatively. Accordingly, any differences between the values of the corrective voltages 46, 48 can only be attributable to the thermoelectric voltages 38. The above-mentioned thermoelectric voltage difference 74 between the thermoelectric voltages 38 can therefore be determined by the simple subtraction of the two corrective voltages 46, 48 determined in FIG. 4 from each other. The remainder of the evaluation then proceeds correspondingly to FIG. 3, as shown in FIG. 5.

1. A method for the measurement of an electric current by an electrical conductor in a vehicle, said electrical conductor comprised of two conductor sections, between which a shunt is connected, the method comprising:
determining an electrical measuring voltage delivered via the shunt;
recording of a first corrective voltage in the direction of the electric current, considered an up-circuit of a given point on the shunt;
recording of a second corrective voltage in the direction of the electric current, considered a down-circuit of said point on the shunt; and
determining the electric current based upon the electrical measuring voltage recorded and a difference between the first corrective voltage and the second corrective voltage.

2. The method as claimed in claim 1, wherein the first corrective voltage and the second corrective voltage are recorded symmetrically to the point.

3. The method as claimed in claim 1, wherein an electrical resistance at a reference temperature by which the first corrective voltage is recorded, is equal to an electrical resistance at the reference temperature by which the second corrective voltage is recorded.

4. The method as claimed in claim 3, wherein the two electrical resistances are assigned an equal temperature coefficient.

5. The method as claimed in claim 1, further comprising:
determining a temperature difference based upon the difference between the first corrective voltage and the second corrective voltage, and
determining the electric current based upon the electrical measuring voltage and the temperature difference recorded.

6. The method as claimed in claim 1, wherein the corrective voltages are determined respectively at a transition between the conductor sections of the electrical conductor and the shunt.

7. The method as claimed in claim 6, further comprising:
determining a temperature voltage difference based upon the difference between the corrective voltages determined respectively at a transition between the conductor sections of the electrical conductor and the shunt, and
determining the electric current based upon the recorded electrical measuring voltage and the temperature voltage difference.

8. The method as claimed in claim 1, wherein the two corrective voltages are recorded at a common voltage tap-off point.

9. A device, which is designed for the execution of the method of claim 1.

10. A current sensor for the measurement of an electric current, comprising:
an electric shunt, via which the electric current to be measured can be routed,
a device as claimed in claim 9.

11. The method as claimed in claim 2, wherein an electrical resistance at a reference temperature by which the first corrective voltage is recorded, is equal to an electrical resistance at the reference temperature by which the second corrective voltage is recorded.
